(19) United States
(12) Patent Application Publication
(10) Pub. No.: US 2018/0166390 A1
(43) Pub. Date: Jun. 14, 2018

(54) PLANAR PACKAGE STRUCTURE AND MANUFACTURING METHOD THEREOF

(71) Applicants: Chao-Ching Yu, Taoyuan City (TW); Chip Win Technology Co., Ltd., Hsinchu County (TW)

(72) Inventors: Chao-Ching Yu, Taoyuan City (TW); Lin-Ta Chung, Hsinchu County (TW); Hsi-Ying Yuan, Hsinchu County (TW); Tung-Chuan Wang, Hsinchu County (TW)

(21) Appl. No.: 15/374,866

(22) Filed: Dec. 9, 2016

(51) Int. Cl. H01L 23/538; H01L 23/31; H01L 23/544; H01L 21/768; H01L 21/52; H01L 21/56; G06K 9/00

(52) U.S. Cl. CPC H01L 23/5389; H01L 23/5386; H01L 23/5384; H01L 23/5383; H01L 23/3142; H01L 2223/54426; H01L 21/76877; H01L 21/52; H01L 21/565; G06K 9/00013; G06K 9/00087; H01L 23/544

(57) ABSTRACT

Provided is a planar package structure and its manufacturing method. The planar package structure totally packages a die to make the die unexposed and to protect the die from impact or scratch. Further, at least one conductive pad of the die is electronically connected to an external electronic circuit through a plurality of wiring patterns and through holes filled with conductive materials. Then, the die may be connected to the external electronic circuit and may be protected from impact or scratch.

### BACKGROUND OF THE INVENTION

### 1. Field of the Invention

The present invention relates to a package structure and a manufacturing method thereof, and particularly to a planar package structure and manufacturing method thereof.

### 2. Description of the Related Art

A package structure of a semiconductor is that a casing contains or covers one or more semiconductor units or integrated circuits, and a material of the casing may be metal, plastic, glass, or ceramic.

When the semiconductor unit or the integrated circuit is etched and cut from a wafer to form a die, the package structure may cover the die to protect the die from impact or scratch. The package structure may provide a contact, and the die may be electronically connected to an external electronic circuit through the contact of the package structure. The package structure may further increase radiating efficiency of the die when the die is working.

With reference to FIGS. 12 to 16, a manufacturing method of a conventional package structure is shown.

As shown in FIG. 12, the manufacturing method of the conventional package structure may firstly provide a carrier 90 and a second substrate 91. A bottom surface of the carrier 90 has an alignment key 901. The second substrate 91 comprises a first surface 911, a second surface 912, and a cavity 913. The first surface 911 of the second substrate 91 faces the carrier 90, and the second substrate 91 is aligned with the alignment key 901 of the carrier 90. Then, the second substrate 91 is mounted on the carrier 90.

As shown in FIG. 13, a die 92 is mounted in the cavity 913 of the second substrate 91. Contact pads 921 of the die 92 are aligned with other alignment keys 902 of the carrier 90, and the die 92 is attached to the carrier 90. Therefore, the contact pads 921 of the die 92 and a circuit pattern 9111 mounted on the first surface 911 of the second substrate 91 are at a same layer.

As shown in FIG. 14, an adhesive material 93 is formed between the second substrate 91 and the die 92, and the adhesive material 93 further covers the second surface 912 of the second substrate 91. Therefore, the die 92 may be firmly mounted in the cavity 913 of the second substrate 91.

As shown in FIG. 15, a first substrate 94 is laminated on the second surface 912 of the second substrate 91 and is adhered to the second surface 912 of the second substrate 91 via the adhesive material 93. Further, a circuit pattern 941 mounted on the surface of the first substrate 94 is aligned with a circuit pattern 9121 mounted on the second surface 912 of the second substrate 91. Then, the circuit pattern 941 of the first substrate 94 and the circuit pattern 9121 of the second substrate 91 are respectively coated with solder paste, and the circuit pattern 941 of the first substrate 94 and the circuit pattern 9121 of the second substrate 91 are soldered together.

As shown in FIG. 16, the carrier 90 is removed from the second substrate 91 by a blade 95.

As shown in FIG. 17, a circuit is formed to be electronically connected to the contact pads 921 of the die 92 and the circuit pattern 9111 mounted on the first surface 911 of the second substrate 91. Then, a dielectric layer covers and protects the circuit.

The manufacturing method of the conventional package structure may provide the carrier 90 at first, and the alignment key 901 and the alignment key 902 are formed on the surface of the carrier 90. When many dies 92 are packaged at the same time, the dies 92 need to be respectively aligned with the alignment keys 901, 902 of the corresponding carriers 90. Then, the dies 92 may be mounted in correct positions such that finished products of the packaged dies 92 may be normally used. Therefore, a great amount of carriers 90 need to be prepared, and finally these carriers 90 need to be respectively removed from the second substrate 91.

The first substrate 94 may be electronically connected to the second substrate 91 by executing four manufacturing steps of the manufacturing method. Four wiring patterns are formed on the first substrate 94 and the second substrate 91, and further two metal bumps need to be soldered on two of the four wiring patterns. In other words, six wiring patterns are formed in the conventional package structure. Therefore, the manufacturing method of the conventional package structure is complicated and needs to be improved.

### SUMMARY OF THE INVENTION

An objective of the present invention is to provide a planar package structure and manufacturing method thereof. The planar package structure may be manufactured without any carrier, and steps of the manufacturing method may be decreased and simplified.

To achieve the foregoing objective, one embodiment of the planar package structure comprises a first substrate, a second substrate, a first adhesive layer, at least one first through hole, a die, a second adhesive layer, a first dielectric layer, a second dielectric layer, and a third dielectric layer. In the embodiment, the planar package structure may be a fan-out type panel package structure.

The second substrate is laminated on a top surface of the first substrate and forms a cavity.

The first adhesive layer is mounted between the first substrate and the second substrate to adhere the first substrate to the second substrate. A first wiring pattern is fowled on a bottom surface of the first substrate. A second wiring pattern is formed on a top surface of the second substrate.

The at least one first through hole is formed through the first substrate, the first adhesive, and the second substrate, and the at least one first though hole is filled with a first conductive material. The first wiring pattern is electronically connected to the second wiring pattern through the first conductive material filled in the at least one first through hole.

The die is mounted in the cavity of the second substrate, and at least one conductive pad is formed on a top surface of the die.

The second adhesive layer is mounted between the die and an inner wall of the cavity of the second substrate to adhere the die to the second substrate.

The first dielectric layer is mounted on the bottom surface of the first substrate, and the first dielectric layer has at least one first opening. The first wiring pattern is exposed from the at least one first opening of the first dielectric layer.

The second dielectric layer is mounted on the top surface of the second substrate, and a plurality of second through holes are formed through the second dielectric layer. The second wiring pattern and the at least one conductive pad of the die are respectively exposed in the plurality of second through holes, and the second through holes are filled with second conductive materials. A third wiring pattern is formed on a top surface of the second dielectric layer, and the third wiring pattern is electronically connected to the second wiring pattern and the at least one conductive pad of the die through the second conductive materials filled in the second through holes.

The third dielectric layer is mounted on the top surface of the second dielectric layer to cover the third wiring pattern.

One embodiment of the manufacturing method of the planar package structure comprises steps of:

providing the first substrate and the second substrate;

mounting the first adhesive layer between the first substrate and the second substrate;

adhering the first substrate to the second substrate by the first adhesive layer;

penetrating the first substrate, the first adhesive layer and the second substrate to form the at least one first through hole;

filling the at least one first through hole with a first conductive material;

forming the first wiring pattern on the bottom surface of the first substrate;

forming the second wiring pattern on the top surface of the second substrate; wherein the first wiring pattern is electronically connected to the second wiring pattern through the first conductive material filled in the at least one first through hole;

aligning the die with the alignment key of the first substrate;

mounting the die in the cavity of the second substrate, wherein the at least one conductive pad is formed on the top surface of the die;

mounting the second adhesive layer between the die and the inner wall of the cavity of the second substrate;

adhering the die to the second substrate by the second adhesive layer;

mounting the first dielectric layer on the bottom surface of the first substrate;

forming the at least one first opening on the first dielectric layer, wherein the first wiring pattern is exposed from the at least one first opening of the first dielectric layer;

mounting the second dielectric layer on the top surface of the second substrate;

penetrating the second dielectric layer to form the second through holes; wherein the second wiring pattern and the at least one conductive pad of the die are respectively exposed in the plurality of second through holes;

filling the second through holes with second conductive materials;

forming the third wiring pattern on the top surface of the second dielectric layer, wherein the third wiring pattern is electronically connected to the second wiring pattern and the at least one conductive pad of the die through the second conductive materials filled in the second through holes; and

mounting the third dielectric layer on the top surface of the second dielectric layer.

The planar package structure may cover the die to make the die unexposed. The conductive pad of the die may be electronically connected to the third wiring pattern through the second conductive materials filled in the second through holes, and may further be electronically connected to the second wiring pattern through the second conductive materials filled in the remaining second through holes. The conductive pad of the die may further be electronically connected to the first wiring pattern through the second conductive materials filled in the at least one first through hole. Further, the first wiring pattern is exposed from the at least one first opening of the first dielectric layer.

Therefore, an external electronic circuit may be electronically connected to the exposed first wiring pattern through the at least one first opening of the first dielectric layer, and the conductive pad of the die may be electronically connected to the external electronic circuit.

The die is totally packaged in the planar package structure and is unexposed. Therefore, the die may be protected from impact or scratch.

Further, the manufacturing method of the planar package structure needs not use any carrier and thus removal of the carrier is unnecessary, and the amount of wiring patterns may be decreased to simplify the manufacturing method.

Other objectives, advantages and novel features of the invention will become more apparent from the following detailed description when taken in conjunction with the accompanying drawings.

### BRIEF DESCRIPTION OF THE DRAWINGS

FIG. 1 is a sectional view of a first embodiment of a planar package structure;

FIGS. 2 to 7 are manufacturing process schematic views of a manufacturing method of the first embodiment of the planar package structure of FIG. 1;

FIGS. 8A and 8B are flowcharts of a manufacturing method of a planar package structure;

FIG. 9 is a sectional view of a second embodiment of a planar package structure;

FIG. 10 is a sectional view of a third embodiment of a planar package structure;

FIG. 11 is a sectional view of a fourth embodiment of a planar package structure; and

FIGS. 12 to 17 are manufacturing process schematic views of a manufacturing method of a conventional package structure.

### DETAILED DESCRIPTION OF THE INVENTION

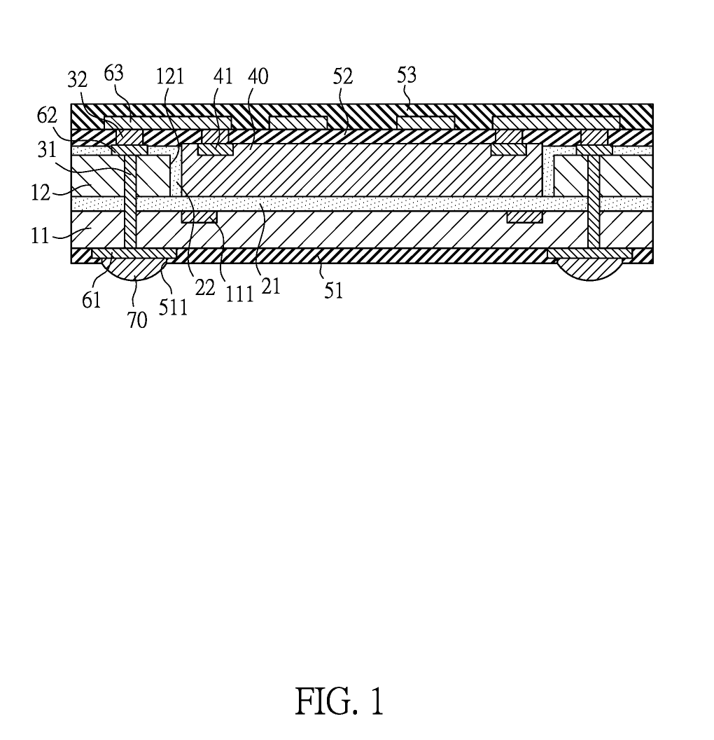

With reference to FIG. 1, the present invention is a planar package structure and manufacturing method thereof. The planar package structure comprises a first substrate 11, a second substrate 12, a first adhesive layer 21, at least one first through hole 31, a die 40, a second adhesive layer 22, a first dielectric layer 51, a second dielectric layer 52, and a third dielectric layer 53.

The second substrate 12 is laminated on a top surface of the first substrate 11 and forms a cavity 121. The first adhesive layer 21 is mounted between the first substrate 11 and the second substrate 12 to adhere the first substrate 11 to the second substrate 12. A first wiring pattern 61 is formed on a bottom surface of the first substrate 11. A second wiring pattern 62 is formed on a top surface of the second substrate 12.

The at least one first through hole 31 is formed through the first substrate 11, the first adhesive 21, and the second substrate 12, and the at least one first though hole 31 is filled with a first conductive material. The first wiring pattern 61 is electronically connected to the second wiring pattern 62 through the first conductive material filled in the at least one first through hole 31.

The die 40 is mounted in the cavity 121 of the second substrate 12, and at least one conductive pad 41 is formed on a top surface of the die 40. In the embodiment, an alignment key 111 is formed on the top surface of the first substrate 11, and the die 40 is aligned with the alignment key 111 to be mounted in the cavity 121 of the second substrate 12.

The second adhesive layer 22 is mounted between the die 40 and an inner wall of the cavity 121 of the second substrate 12 to adhere the die 40 to the second substrate 12.

The first dielectric layer 51 is mounted on the bottom surface of the first substrate 11, and the first dielectric layer 51 has at least one first opening 511, and the first wiring pattern 61 is exposed from the at least one first opening 511 of the first dielectric layer 51.

The second dielectric layer 52 is mounted on the top surface of the second substrate 12, and a plurality of second through holes 32 are formed through the second dielectric layer 52. The second wiring pattern 62 and the at least one conductive pad 41 of the die 40 arc respectively exposed in the plurality of second through holes 32, and the second through holes 32 are filled with second conductive materials. A third wiring pattern 63 is formed on a top surface of the second dielectric layer 52, and the third wiring pattern 63 is electronically connected to the second wiring pattern 62 and the at least one conductive pad 41 of the die 40 through the second conductive materials filled in the second through holes 32.

The third dielectric layer 53 is mounted on the top surface of the second dielectric layer 52 to cover the third wiring pattern 63.

The planar package structure may cover the die 40 to make the die 40 unexposed. The at least one conductive pad 41 of the die 40 may be electronically connected to the third wiring pattern 63 through the second conductive materials filled in the second through holes 32, and may be further electronically connected to the second wiring pattern 62 through the second conductive materials filled in the remaining second through holes 32. The at least one conductive pad 41 of the die 40 may further he electronically connected to the first wiring pattern 61 through the first conductive material filled in the at least one first through hole 31.

Therefore, an external electronic circuit may be electronically connected to the exposed first wiring pattern 61 through the at least one first opening 511 of the first dielectric layer 51, and the at least one conductive pad 41 of the die 40 may be electronically connected to the external electronic circuit.

The die 40 is totally packaged in the planar package structure and is unexposed. Therefore, the die 40 may be protected from impact or scratch.

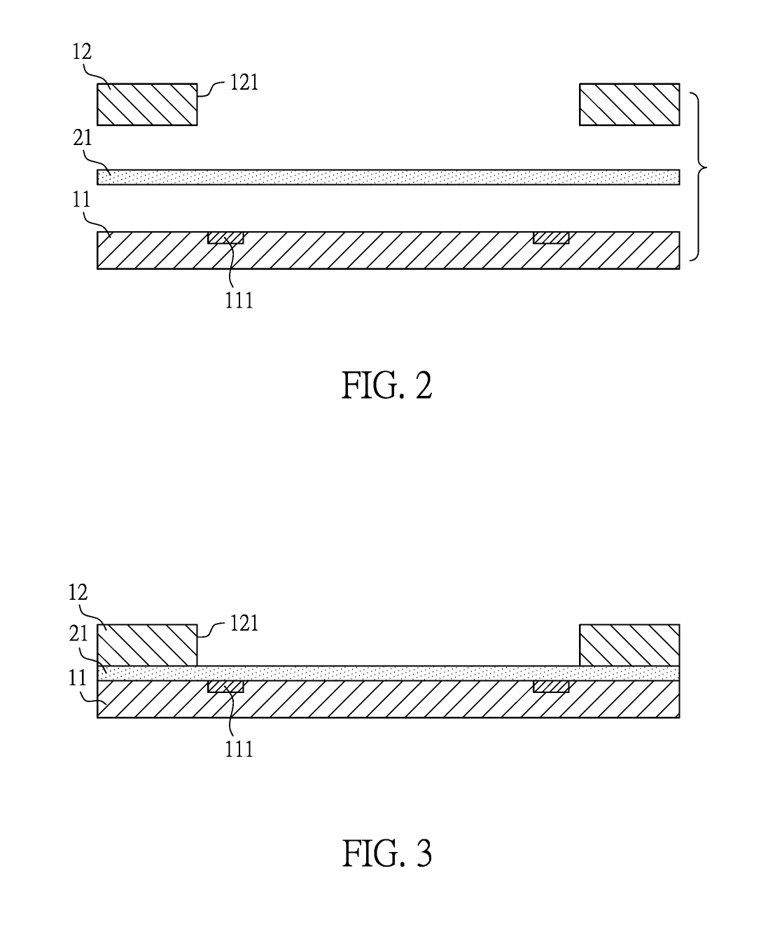

With reference to FIGS. 2 to 7, manufacturing process schematic views of the manufacturing method of the first embodiment of the planar package structure are shown.

As shown in FIG. 2, the first substrate 11 and the second substrate 12 are provided, and the first adhesive layer 21 is mounted between the first substrate 11 and the second substrate 12.

As shown in FIG. 3, the first adhesive layer 21 may adhere the first substrate 11 to the second substrate 12.

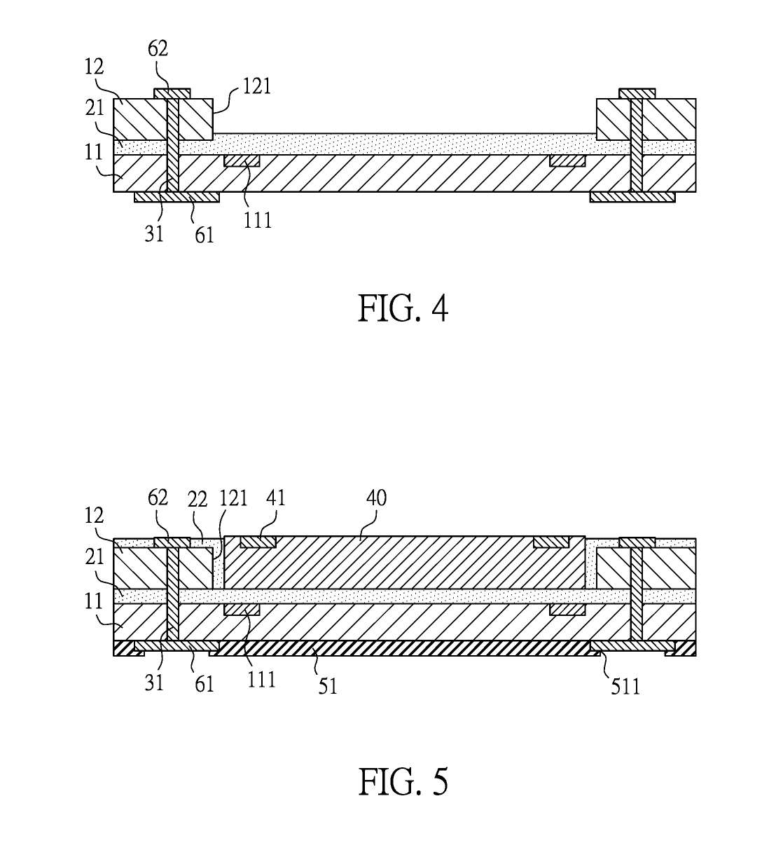

As shown in FIG. 4, the first substrate 11, the first adhesive layer 21, and the second substrate 12 arc penetrated to form the at least one first through hole 31. The at least one first through hole 31 is filled with the first conductive material. Then, the first wiring pattern 61 is formed on the bottom surface of the first substrate 11 by processes such as metal plating, exposure, developer, and etching. The second wiring pattern 62 is formed on the top surface of the second substrate 12 by processes such as metal plating, exposure, developer, and etching. The first wiring pattern 61 is electronically connected to the second wiring pattern 62 through the first conductive material filled in the at least one first through hole 31.

As shown in FIG. 5, the die 40 is aligned with the alignment key 111 of the first substrate 11, and is mounted in the cavity 121 of the second substrate 12. The at least one conductive pad 41 is formed on the top surface of the die 40. The second adhesive layer 22 is mounted between the die 40 and the inner wall of the cavity 121 of the second substrate 12 to adhere the die 40 to the second substrate 12. The first dielectric layer 51 is mounted on the bottom surface of the first substrate 11, and the first dielectric layer 51 has the at least one first opening 511. Further, the first wiring pattern 61 is exposed from the at least one first opening 511 of the first dielectric layer 51.

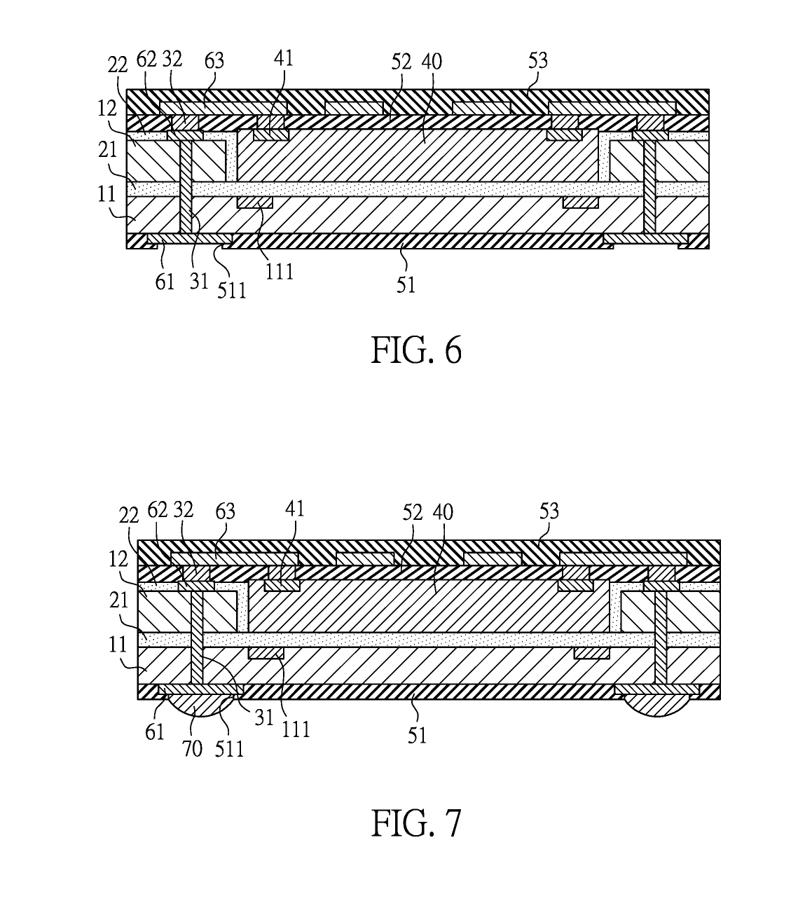

As shown in FIG. 6, the second dielectric layer 52 is mounted on the top surface of the second substrate 12, and the second dielectric layer 52 is penetrated to form the second through holes 32. The second wiring pattern 62 and the at least one conductive pad 41 of the die 40 are respectively exposed in the different second through holes 32, and are filled with second conductive materials. The third wiring pattern 63 is formed on the top surface of the second dielectric layer 52, and the third wiring pattern 63 is electronically connected to the second wiring pattern 62 and the at least one conductive pad 41 of the die 40 through the second conductive materials filled in the second through holes 32. The third dielectric layer 53 is mounted on the top surface of the second dielectric layer 52 to cover the third wiring pattern 63.

Besides, as shown in FIG. 7, an opening conductive material 70 may further be filled in the at least one first opening 511 of the first dielectric layer 51. The opening conductive material 70 may protrude from a bottom surface of the first dielectric layer 51, and may be electronically connected to the first wiring pattern 61 through the at least one first opening 511 of the first dielectric layer 51. Therefore, the first wiring pattern 61 may be more easily electronically connected to the external electronic circuit through the opening conductive material 70. In the embodiment, the opening conductive material may be a solder joint.

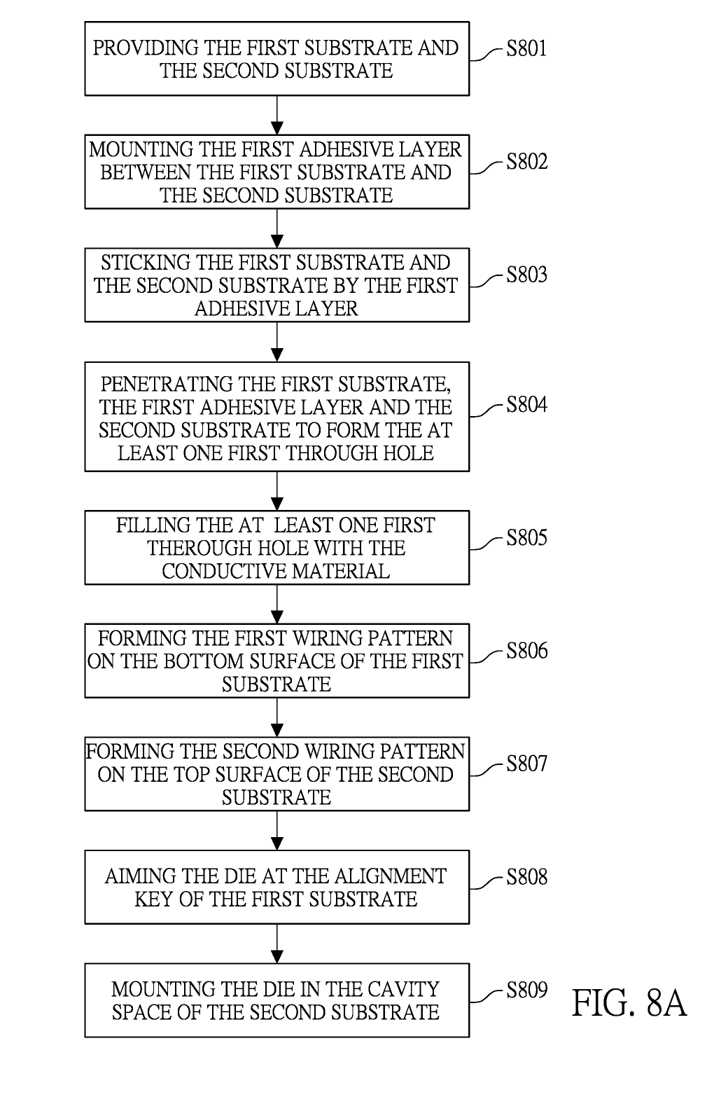

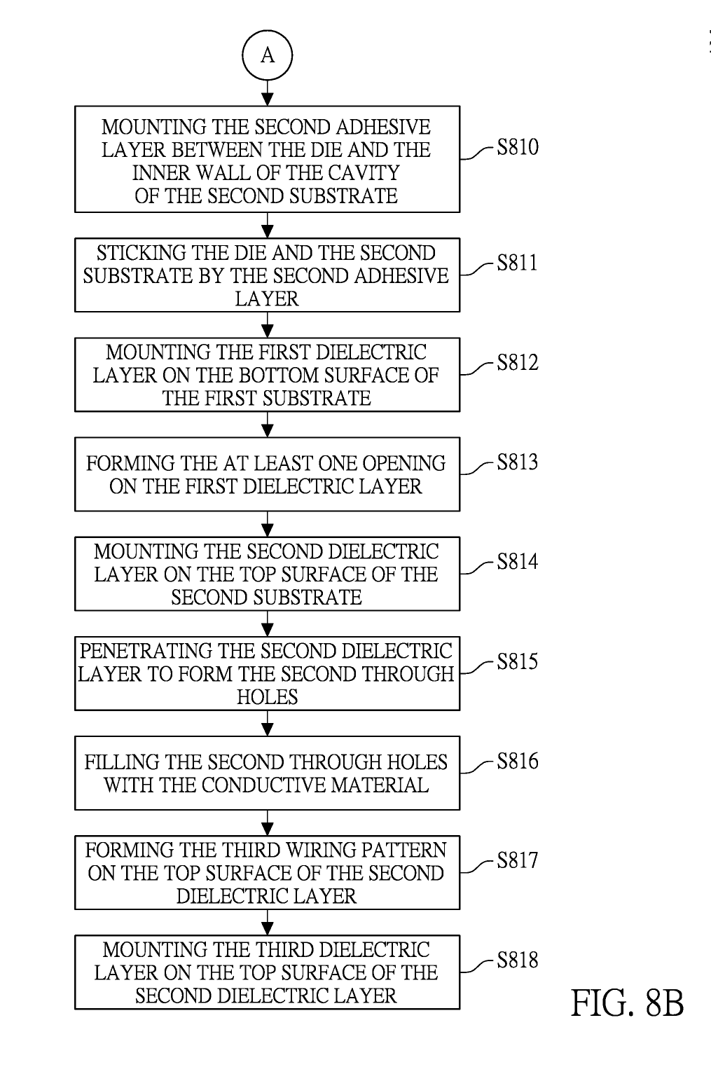

With reference to FIGS. 8A and 8B, the manufacturing method of the first embodiment of the planar package structure may comprise the steps of:

providing the first substrate 11 and the second substrate 12 (S801);

mounting the first adhesive layer 21 between the first substrate 11 and the second substrate 12 (S802);

adhering the first substrate 11 to the second substrate 12 by the first adhesive layer 21 (S803);

penetrating the first substrate 11, the first adhesive layer 21 and the second substrate 12 to form the at least one first through hole 31 (S804);

filling the at least one first through hole 31 with a first conductive material (S805);

forming the first wiring pattern 61 on the bottom surface of the first substrate 11 (S806);

forming the second wiring pattern 62 on the top surface of the second substrate 12 (S807); wherein the first wiring pattern 61 is electronically connected to the second wiring pattern 62 through the first conductive material filled in the at least one first through hole 31;

aligning the die 40 with the alignment key 111 of the first substrate 11 (S808);

mounting the die 40 in the cavity 121 of the second substrate 12 (S809); wherein the at least one conductive pad 41 is formed on the top surface of the die 40;

mounting the second adhesive layer 22 between the die 40 and the inner wall of the cavity 121 of the second substrate 12 (S810);

adhering the die 40 to the second substrate 12 by the second adhesive layer 22 (S811);

mounting the first dielectric layer 51 on the bottom surface of the first substrate 11 (S812);

forming the at least one first opening 511 on the first dielectric layer 51 (S813); wherein the first wiring pattern 61 is exposed from the at least one first opening 511 of the first dielectric layer 51;

mounting the second dielectric layer 52 on the top surface of the second substrate 12 (S814);

penetrating the second dielectric layer 52 to form the second through holes 32 (S815); wherein the second wiring pattern 62 and the at least one conductive pad 41 of the die 40 are respectively exposed in the different second through holes 32;

filling the second through holes 32 with second conductive materials (S816);

forming the third wiring pattern 63 on the top surface of the second dielectric layer 52 (S817); wherein the third wiring pattern 63 is electronically connected to the second wiring pattern 62 and the at least one conductive pad 41 of the die 40 through the second conductive materials filled in the second through holes 32; and

mounting the third dielectric layer 53 on the top surface of the second dielectric layer 52 (S818).

The planar package structure may cover the die 40 to make the die 40 unexposed. Therefore, the die 40 may he protected from impact or scratch. Further the manufacturing method of the planar package structure need not use any carrier and thus removal of the carrier is unnecessary, and the amount of wiring patterns may be decreased to simplify the manufacturing method.

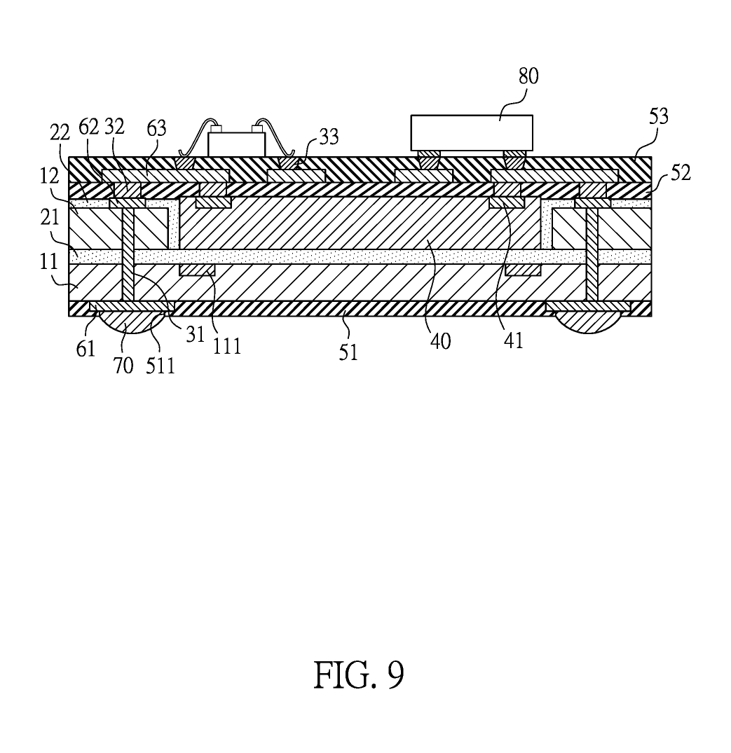

With reference to FIG. 9, the third dielectric layer 53 has a plurality of third through holes 33. The third wiring pattern 63 is exposed from the third through holes 33, and the third through holes 33 are filled with third conductive materials. Therefore, circuit units 80 may be mounted on a top surface of the third dielectric layer 53, and the circuit unit 80 may he electronically connected to the third wiring pattern 63 through the third conductive materials filled in the third through holes 33. Then, the circuit unit 80 may be connected to the planar package structure to form a system in package (SIP) module. In the embodiment, the circuit unit 80 may be a flip-chip integrated circuit or a passive device.

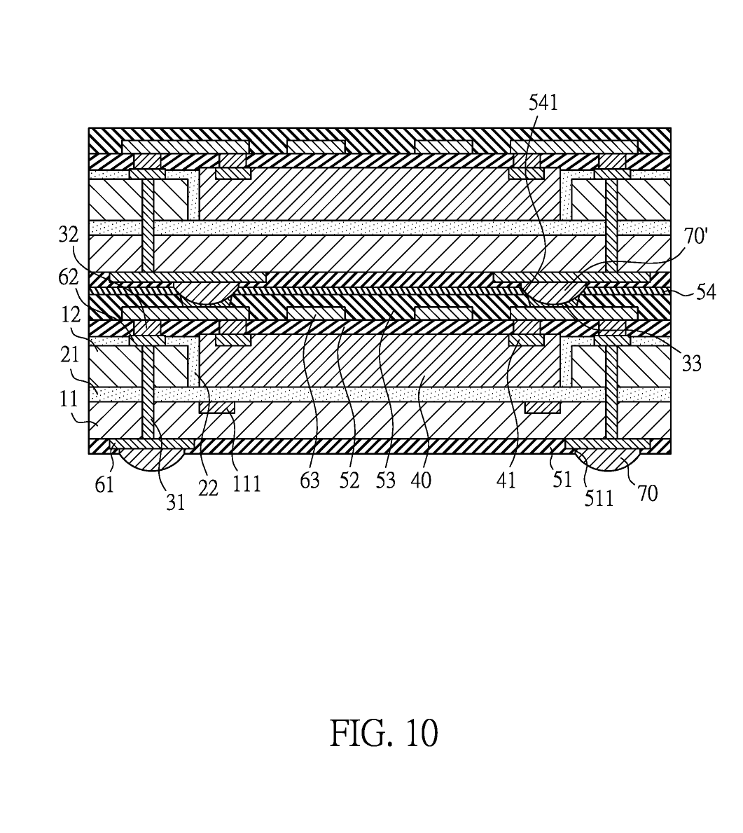

With reference to FIG. 10, a fourth dielectric layer 54 is formed on the third dielectric layer 53. The fourth dielectric layer 54 has a plurality of fourth openings 541. The fourth openings 541 of the fourth dielectric layer 54 are connected to the third through holes 33, and the third through holes 33 are filled with the third conductive materials. Therefore, another planar package structure may be mounted on a top surface of the fourth dielectric layer 54, and the solder joint 70′ or the conductive materials of said another planar package structure may be electronically connected to the third conductive materials filled in the third through holes 33 through the fourth openings 541 of the fourth dielectric layer 54. Then, two planar package structures may be electronically connected together to form a package on package (PoP) structure.

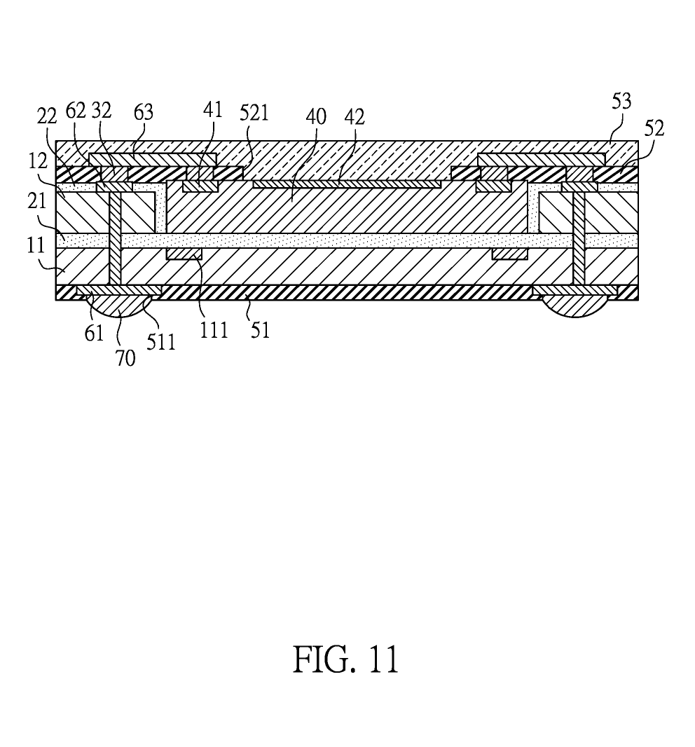

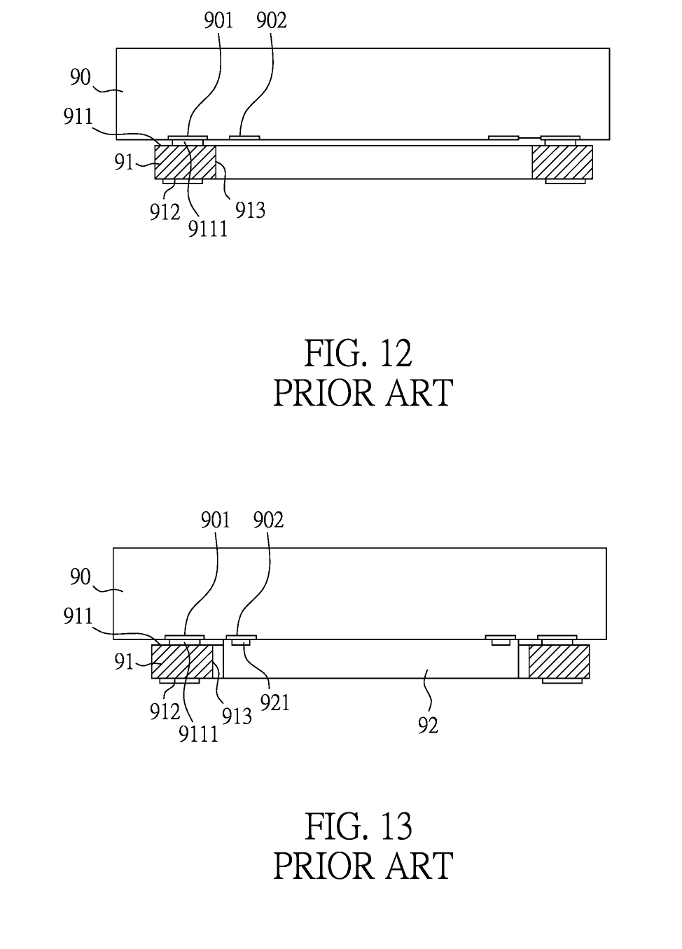

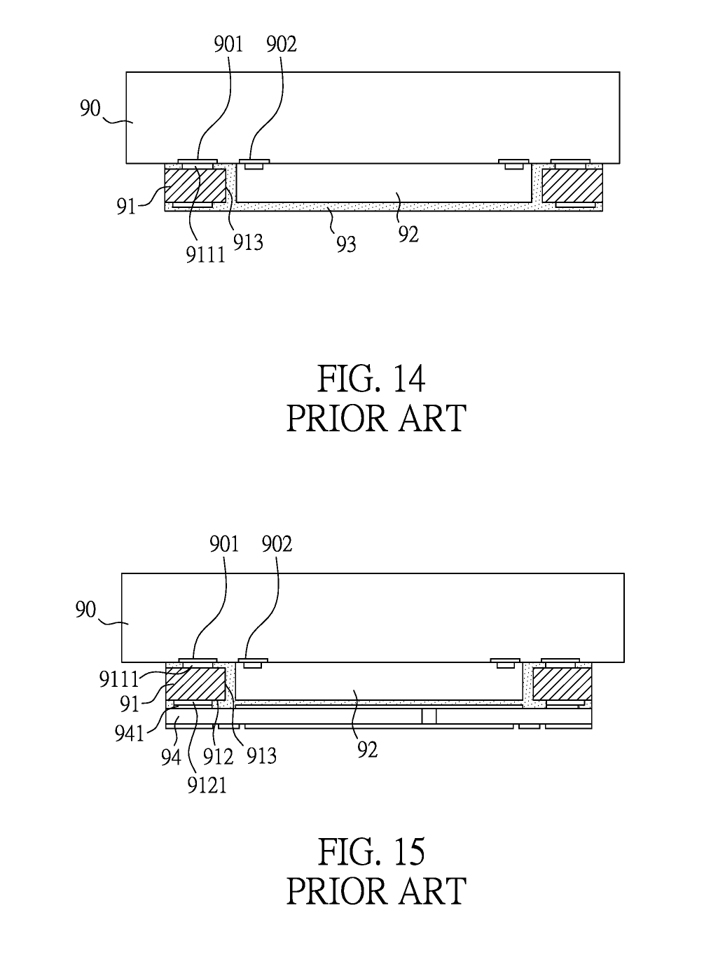

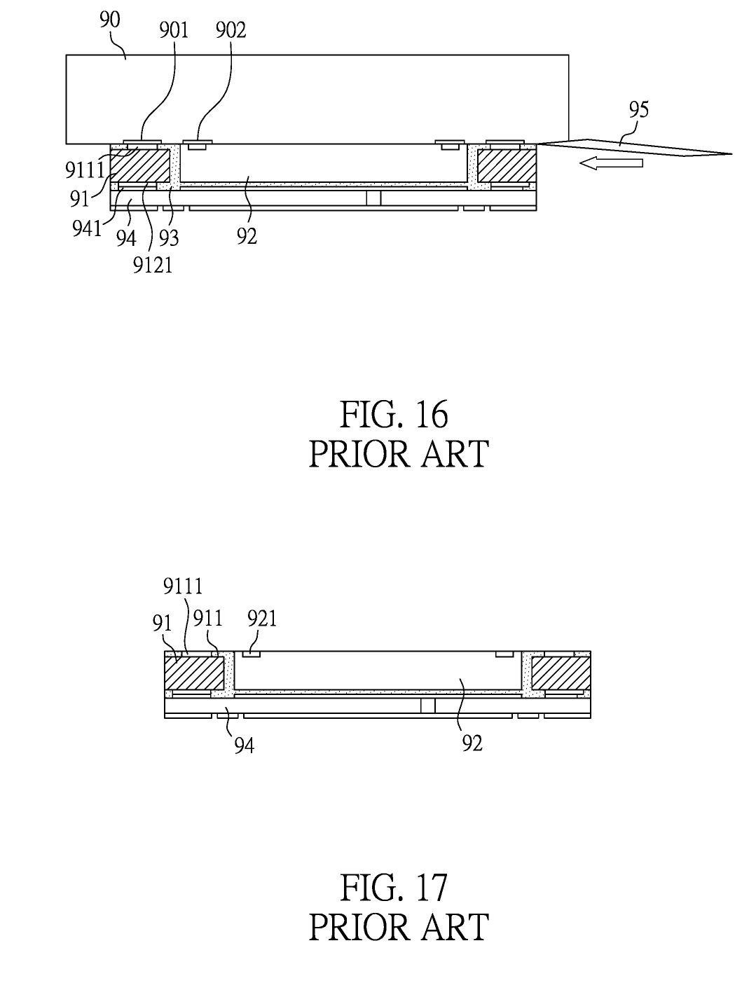

With reference to FIG. 11, the die 40 may be a fingerprint recognition chip, and the top surface of the die 40 has a sensor area 42. The second dielectric layer 52 further has a second opening 521, and the second opening 521 of the second dielectric layer 52 is aligned with the sensor area 42 of the die 40. Then, the sensor area 42 of the die 40 may be exposed. The third dielectric layer 53 is a wear-resistant material and covers the second opening 521 of the second dielectric layer 52. Therefore, when a fingerprint is to be recognized, a user may put a finger on a position of the third dielectric layer 53 corresponding to the second opening 521 of the second dielectric layer 52. Then, the sensor area 42 of the die 40 may sense the finger of the user for fingerprint recognition of the user.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed

1

s:

1. A planar package structure, comprising:
a first substrate, wherein a first wiring pattern is formed on a bottom surface of the first substrate;
a second substrate, laminated on a top surface of the first substrate, wherein a cavity is formed in the second substrate, and a second wiring pattern is formed on a top surface of the second substrate;
a first adhesive layer, mounted between the first substrate and the second substrate to adhere the first substrate to the second substrate;
at least one first through hole, formed through the first substrate, the first adhesive, and the second substrate, wherein the at least one first though hole is filled with a first conductive material, and the first wiring pattern is electronically connected to the second wiring pattern through the first conductive material filled in the at least one first through hole;
a die, mounted in the cavity of the second substrate, wherein at least one conductive pad is formed on a top surface of the die;
a second adhesive layer, mounted between the die and an inner wall of the cavity of the second substrate to adhere the die to the second substrate;
a first dielectric layer, mounted on the bottom surface of the first substrate, wherein the first dielectric layer has at least one first opening, and the first wiring pattern is exposed from the at least one first opening of the first dielectric layer;
a second dielectric layer, mounted on the top surface of the second substrate, wherein multiple second through holes are formed through the second dielectric layer, the second wiring pattern and the at least one conductive pad of the die are respectively exposed from the multiple second through holes, and the second through holes are filled with second conductive materials, wherein a third wiring pattern is formed on a top surface of the second dielectric layer, and the third wiring pattern is electronically connected to the second wiring pattern and the at least one conductive pad of the die through the second conductive materials filled in the second through holes; and
a third dielectric layer, mounted on the top surface of the second dielectric layer to cover the third wiring pattern.

2. The planar package structure as claimed in claim 1, wherein:
an alignment key is formed on the top surface of the first substrate; and
the die is aligned with the alignment key of the first substrate.

3. The planar package structure as claimed in claim 1, wherein:
the at least one first opening of the first dielectric layer is filled with an opening conductive material; and
the opening conductive material filled in the at least one first opening of the first dielectric layer protrudes from a bottom surface of the first dielectric layer and is electronically connected to the first wiring pattern through the at least one first opening of the first dielectric layer.

4. The planar package structure as claimed in claim 3, wherein the opening conductive material filled in the at least one first opening of the first dielectric layer is a solder joint.

5. The planar package structure as claimed in claim 1, wherein:
the third dielectric layer has a plurality of third through holes; and
the third wiring pattern is exposed from the third through holes, and the third through holes are filled with third conductive materials.

6. The planar package structure as claimed in claim 2, wherein:
the third dielectric layer has a plurality of third through holes; and
the third wiring pattern is exposed from the third through holes, and the third through holes are filled with third conductive materials.

7. The planar package structure as claimed in claim 3, wherein:
the third dielectric layer has a plurality of third through holes; and
the third wiring pattern is exposed from the third through holes, and the third through holes are filled with third conductive materials.

8. The planar package structure as claimed in claim 5, wherein:
a fourth dielectric layer is formed on the third dielectric layer;
the fourth dielectric layer has a plurality of fourth openings; and
the fourth openings of the fourth dielectric layer are connected to the third through holes, and the third through holes are filled with the third conductive materials.

9. The planar package structure as claimed in claim 6, wherein:
a fourth dielectric layer is formed on the third dielectric layer;
the fourth dielectric layer has a plurality of fourth openings; and
the fourth openings of the fourth dielectric layer are connected to the third through holes, and the third through holes are filled with the third conductive materials.

10. The planar package structure as claimed in claim 7, wherein:
a fourth dielectric layer is formed on the third dielectric layer;
the fourth dielectric layer has a plurality of fourth openings; and
the fourth openings of the fourth dielectric layer are connected to the third through holes, and the third through holes are filled with the third conductive materials.

11. The planar package structure as claimed in claim 1, wherein:
the die is a fingerprint recognition chip, and a sensor area is formed on the top surface of the die;
the second dielectric layer has a second opening, and the second opening of the second dielectric layer is aligned with the sensor area of the die; and
the third dielectric layer is a wear-resistant material and covers the second opening of the second dielectric layer.

12. The planar package structure as claimed in claim 2, wherein:
the die is a fingerprint recognition chip, and a sensor area is formed on the top surface of the die;
the second dielectric layer has a second opening, and the second opening of the second dielectric layer is aligned with the sensor area of the die; and
the third dielectric layer is a wear-resistant material and covers the second opening of the second dielectric layer.

13. The planar package structure as claimed in claim 3, wherein:
the die is a fingerprint recognition chip, and a sensor area is formed on the top surface of the die;
the second dielectric layer has a second opening, and the second opening of the second dielectric layer is aligned with the sensor area of the die; and
the third dielectric layer is a wear-resistant material and covers the second opening of the second dielectric layer.

14. A manufacturing method of a planar package structure, comprising steps of:
providing a first substrate and a second substrate;
mounting a first adhesive layer between the first substrate and the second substrate;
adhering the first substrate to the second substrate by the first adhesive layer;
penetrating the first substrate, the first adhesive layer and the second substrate to form at least one first through hole;
filling the at least one first through hole with a first conductive material;
forming a first wiring pattern on a bottom surface of the first substrate;
forming a second wiring pattern on a top surface of the second substrate; wherein the first wiring pattern is electronically connected to the second wiring pattern through a first conductive material filled in the at least one first through hole;
aiming a die at an alignment key of the first substrate;
mounting the die in a cavity of the second substrate; wherein at least one conductive pad is formed on a top surface of the die;
mounting a second adhesive layer between the die and an inner wall of the cavity of the second substrate;
adhering the die to the second substrate by the second adhesive layer;
mounting a first dielectric layer on the bottom surface of the first substrate;
forming at least one first opening on the first dielectric layer; wherein the first wiring pattern is exposed from the at least one first opening of the first dielectric layer;
mounting the second dielectric layer on the top surface of the second substrate;
penetrating the second dielectric layer to form a plurality of second through holes;
wherein the second wiring pattern and the at least one conductive pad of the die are respectively exposed in the plurality of second through holes;
filling the second through holes with second conductive materials;
forming a third wiring pattern on a top surface of the second dielectric layer; wherein the third wiring pattern is electronically connected to the second wiring pattern and the at least one conductive pad of the die through the second conductive materials filled in the second through holes; and
mounting a third dielectric layer on the top surface of the second dielectric layer.

15. The manufacturing method of the planar package structure as claimed in claim 14, wherein:
an alignment key is formed on a top surface of the first substrate;
the die is aligned with the alignment key to be mounted in the cavity of the second substrate.

16. The manufacturing method of the planar package structure as claimed in claim 14, wherein:
the at least one first opening of the first dielectric layer is filled with an opening conductive material;
the opening conductive material filled in the at least one first opening of the first dielectric layer protrudes from a bottom surface of the first dielectric layer and is electronically connected to the first wiring pattern through the at least one first opening of the first dielectric layer.

17. The manufacturing method of the planar package structure as claimed in claim 16, wherein the opening conductive material filled in the at least one first opening of the first dielectric layer is a solder joint.

18. The manufacturing method of the planar package structure as claimed in claim 14, wherein:
the third dielectric layer has a plurality of third through holes;
the third wiring pattern is exposed from the third through holes, and the third through holes are filled with third conductive materials.

19. The manufacturing method of the planar package structure as claimed in claim 14, wherein:
a fourth dielectric layer is formed the third dielectric layer;
the fourth dielectric layer has a plurality of fourth openings;
the fourth openings of the fourth dielectric layer are connected to the third through holes, and the third through holes are filled with third conductive materials.

20. The manufacturing method of the planar package structure as claimed in claim 14, wherein:
the die is a fingerprint recognition chip, and a sensor area is formed on the top surface of the die;
the second dielectric layer has a second opening, and the second opening of the second dielectric layer is aligned with the sensor area of the die;
the third dielectric layer is a wear-resistant material and covers the second opening of the second dielectric layer.
